SEQUENCE LISTING (2 sequences)

SEQ ID NO: 1 - DNA, 20 bp, artificial
  Sequence description Oligomer (20-mer), (see p. 13)
ttttttcggatacccaagga

SEQ ID NO: 2 - DNA, 21 bp, artificial
  Sequence description Oligomer (21-mer), (see p. 13)
gtctccttgggtatccgatgt

(19) United States
(12) Patent Application Publication
(10) Pub. No.: US 2009/0053481 A1
(43) Pub. Date: Feb. 26, 2009

(54) METHOD FOR SUCCESSIVELY FUNCTIONALIZING A SUBSTRATE AND MICROSTRUCTURE IS OBTAINABLE BY SAID METHOD

(76) Inventors: Guillaume Delapierre, Vif (FR); Cyril Delattre, Grenoble (FR)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 11/997,477

(22) PCT Filed: Aug. 2, 2006
(86) PCT No.: PCT/EP06/07665

§ 371 Date: Sep. 30, 2008

(30) Foreign Application Priority Data
Aug. 2, 2005 (FR) 0508221

(51) Int. Cl. B32B 3/10; B05D 3/10; H01L 21/30

(52) U.S. Cl. 428/195.1; 427/154; 438/758; 257/E21.211

(57) ABSTRACT

A method for successively functionalizing a substrate whose surface is provided with at least two areas (1, 2) made up of different materials, with at least one chemical substrate, characterized in that the functionalization is carried out without masking and consists (a) in functionalizing a first area (1) without masking the second area (2) or possible successive areas by transforming the substrate with the aid of a chemical substance X¹, wherein the first area material reactivity is greater with respect to the reactivity of the substance X¹ than the reactivity of the other possible successive areas with respect thereto, and (b1) in treating the second area (2) or the other possible successive areas with a chemical substance Y¹ for removing reaction products deposited on said areas during the functionalization from the areas of the substance X¹ and/or the possible successive areas without damaging the functionalized surface of the first area.

The invention relates to a method for successively functionalizing a substrate and to the microstructure obtained by said method. The word “functionalization” defines the action of attaching or of grafting a chemical molecule onto a support. The aim of this functionalization is to confer specific properties on said support (wettability, adsorption, neutral or charged surface, chemical reactivity for the grafting of chemical or biological molecules) . In particular, the invention relates to a method for successively functionalizing a substrate, whose surface is provided with at least two areas made up of different materials, with at least one chemical substance without masking.

Conferring very specific surface properties at the surface of a microsystem (microstructure) is an important problem in the microtechnology field. It is even more important to be able to provide these various properties on the same support made up of various areas. Each area can thus produce different properties.

Currently, the technique most commonly employed uses the succession of the following steps (FIG. 1):
masking the area 2,
functionalizing the area 1,
demasking the area 2,
optionally, masking the area 1,
functionalizing the area 2,
if the area 1 has been masked, demasking this area.

Surface functionalization is often provided by reacting an organic silane on a layer of oxide, for example SiO₂. Numerous examples concerning the preparation of surfaces comprising hydrophilic and hydrophobic areas, carried out according to the scheme indicated in FIG. 1, will be noted. The application of the organic layer can be carried out, for example, by dip-coating in an aqueous phase (cf. “Nanoliter liquid metering in microchannels using hydrophobic patterns” Anal. Chem. 2000, 72, 4100-4109), or in a gas phase, by embossing (cf. “Chemical nano-patterning using hot embossing lithography”, Microelectronics Engineering 2002, 61-62, 423-428), by depositing, or by spin-coating (cf. “Automatic transportation of a droplet on a wettability gradient surface”, 7th International Conference on miniaturized Chemical and Biochemical analysis systems, Oct. 5-9 2003, Squaw Valley, Calif. (USA)).

The order of these steps may also be conventionally the following, as demonstrated in FIG. 2:
functionalizing the entire surface,
masking the area 1 (functionalization to be preserved),
degrading the layer of chemical functionalization on the area 2, for example by means of O₂ plasma,
functionalizing the area 2,
demasking the area 1.

WO-A-02/16023 describes, for example, these two types of approach.

US 2005/0014151 describes a method, known as SMAP (selective molecular assembly patterning technique), which uses three variants in order to selectively functionalize surface areas of a substrate:

One variant uses monolayers of alkane phosphates which form self-assembled monolayers. The other variant uses polyionic polymers due to their electrostatic nature and hydrophobic polymers. The chemical functionalization in this document is therefore carried out only by selective adsorption at the surface of an area to be functionalized with molecules.

In all these methods, certain drawbacks are apparent:

In general, the masking of the areas is done with a polymer. The simultaneous presence of the submolecular substances [instead of “the chemistry”] (in particular solvents) and of this polymer (photosensitive or nonphotosensitive) leads to compatibility problems. In order to bypass this problem, the resin can optionally be replaced with a metal deposit, but, firstly, this involves a more laborious technology (metal deposition, resin deposition, photolithography to open up reactive areas, etching), and, secondly, the metals are also attacked by strong acids.

In the second situation (FIG. 2), the resin directly covers the functionalized surface which can then be contaminated. It is in fact quite difficult to clean surfaces of this type completely without damaging the functionalization layer.

In order to bypass these problems, solutions have been proposed in specific cases. Note will in particular be made of the patents filed by Alchimer (published as WO-A-2004/019385, WO-A-2004/018349), which all relate to the electrografting of organic polymers onto semiconducting and conducting materials. The localization of the functionalization is then ensured by electrical targeting of the areas. However, it is difficult to precisely target locations electrically. The drawback of this method is that it requires the presence of electrical contacts which can make the objects produced more complex and increase their cost. In addition, in this technology, the presence of a gap between the electrodes is absolutely necessary and said electrodes cannot therefore be completely contiguous.

The objective of the present invention is therefore to avoid the problems of the prior art and to propose a suitable method for functionalizing microstructures.

The present invention therefore relates to a method for successively functionalizing a substrate, whose surface is provided with at least two areas made up of different materials, with at least one chemical substance, characterized in that the functionalization is carried out without masking and in that it comprises the steps of:
(a) functionalizing a first area without masking the second area or the possible successive areas by transforming the substrate with a chemical substance X¹, wherein the reactivity of the first-area material is greater with respect to the substance X¹ than the reactivity of the materials of the possible successive areas with respect thereto, and forming a covalent bond between the substance X¹ and the first-area material, and
(b1) treating the second area and/or the possible successive areas with a chemical substance Y¹ in order to clean from these areas the substance X¹ and/or its reaction products, which have been deposited on these areas during the functionalization of the first area, without damaging the functionalized surface of the first area.

The formation of a covalent bond between the substance X¹ and the first-area material provides increased stability of the layer consisting of the substance X¹ on the substrate, compared, for example, to a layer obtained by simple chemical adsorption.

The present invention also relates to a microstructure containing areas which consist of various materials, wherein at least one area is functionalized by chemical bonding, which can be carried out by a method according to the method of the present invention.

### BRIEF DESCRIPTION OF THE DRAWINGS

Other features and advantages of the invention will emerge from the description which follows, with reference to the figures of the attached drawings. The exemplary embodiments described with reference to the drawings attached hereto are in no way limiting.

FIG. 1 illustrates the conventional method of localization (functionalization) according to the prior art.

FIG. 2 illustrates another conventional method of localization (functionalization) according to the prior art.

FIG. 3 illustrates the method according to an exemplary embodiment of the present invention.

FIG. 4 illustrates hybridization on a double-functionalized Si/SiO₂ substrate.

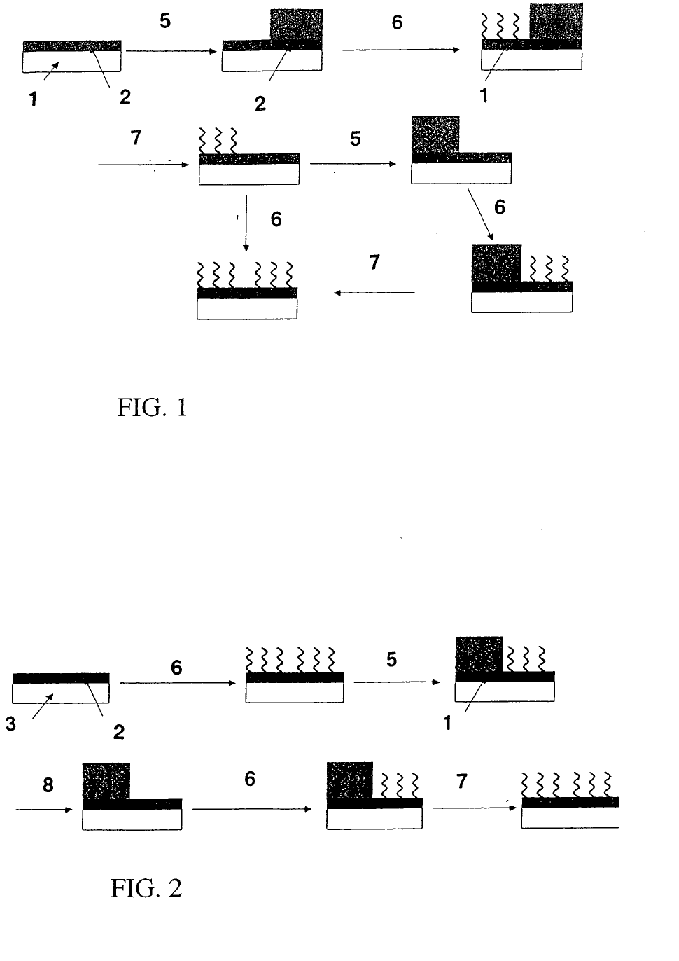

FIG. 1 illustrates the method of functionalization according to the prior art on a support 3 of a microstructure. An area 2 is masked in a first step 5. Next, the area 1 is functionalized in a second step 6 and, subsequently, the area 2 is demasked. If the area 1 is masked in a step 5, this is followed by a step 6 of functionalizing the area 2 and a demasking 7 of the area 1. Alternatively, the area 2 could be functionalized directly after the demasking of the area 2. FIG. 2 illustrates another method of functionalization according to the prior art. The order of these steps is in this case the following:
functionalizing 6 the entire surface,
masking 5 the area 1 (functionalization to be preserved),
degrading 8 the chemical layer on the area 2, for example by means of O₂ plasma,
functionalizing 6 the area 2,
demasking 7 the area 1.

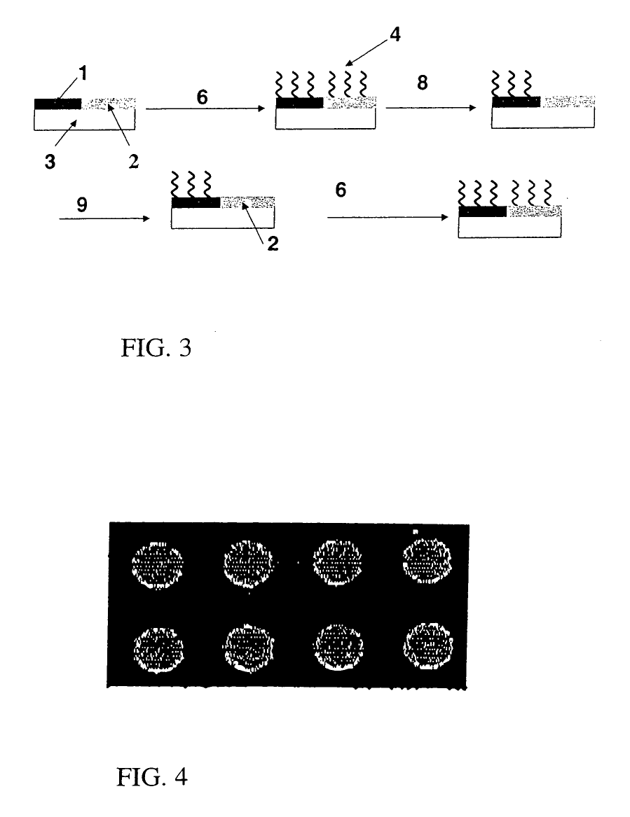

FIG. 3 illustrates the method according to an exemplary embodiment of the present invention. There are two areas 1 and 2 on a substrate 3. In a first step 6, the area 1 is functionalized by reaction, forming a covalent bond, by transforming the substrate with a chemical substance. Some parts of this chemical substance X¹ also react with the area 2.

Consequently, the area 2 is treated with a chemical substance Y¹ in order to clean from these areas the substance X¹ and/or its reaction products, which have been deposited on these areas during the functionalization of the first area, without damaging the functionalized surface of the first area. After the cleaning, the area 2 is activated by chemical or physical activation (step 9) and subsequently functionalized (step 6). Functionalization of a substrate of the various areas is therefore obtained through the formation of covalent bonds.

In the method of the present invention, it is advantageous to also carry out the following step:
(c) functionalizing a second area without masking the successive areas by transforming the substrate with a chemical substance X² different than X¹, wherein the reactivity of the second-area material is greater with respect to the substance X² than the reactivity of the other materials with respect thereto, and forming a covalent bond between the substance X² and the second-area material; and eliminating from the third area or from the possible successive areas, when these areas are present.

In addition, in the present invention, it is preferable to carry out, before the functionalization, the following step:
(b2) chemically or physically activating the second area and the possible successive areas with a view to functionalization, by treating with a chemical substance Y² different than the chemical substances X¹ and X².

Steps (b1), (b2) and/or (c) could be repeated one or more times, for example using, in steps (a) and (c), chemical substances X different than X¹ and X² and, in steps (b1) and/or (b2), chemical substances Y different than Y¹ and than Y².

It is also preferable for step (b1) and/or step (b2) to be carried out in an acidic or basic medium.

In a preferable use, there is at least one area 1 made up of conducting or semiconducting materials or doped insulators, that can react thermally, photochemically or mechanochemically (scribing) with chemical substances X¹, X² or X, the molecules of which possess chemical functionalization reactive with respect to these materials.

Preferred molecules X¹ have groups of the type alkene, alkyne, halogen, diazo, thio, doubly or triply coordinate phosphorus atom (phosphine, phosphinine), aldehyde, alcohol.

Preferred molecules X² have groups of the type silane, siloxane, pentacoordinated phosphorus atom (phosphate, phosphonate).

Advantageously, the conducting or semiconducting materials are selected from those of the group comprising silicon, crystalline or amorphous carbon, optionally n-doped or p-doped, and metals. The preferred metals are gold, silver, copper, nickel and aluminum. Preferable materials are silicon, germanium, and doped carbon in crystalline or amorphous form (graphite, carbon nanotubes, monocrystalline or polycrystalline diamond).

Preferable combinations of materials of various areas are gold/Si oxide, Si/Si oxide, aluminum/Si oxide, Si/Si nitride, and gold/Si oxide/Si.

In another preferable use of the present invention, there is at least one area 2 made up of a material selected from those of the group comprising metal or semimetallic nitrides (Si₃N₄, etc) or oxides (glass, quartz, pyrex, SiO₂, TiO₂, etc), or a mixture of these materials, and polymers such as poly(dimethylsiloxane) (PDMS), acrylic polymers such as PMMA, etc.

Cleaning and activating steps could therefore be carried out in an acidic or basic medium with chemical substances Y¹, Y² or Y, for instance HF, at various dilutions and optionally buffered, an H₂SO₄/H₂O₂ mixture in varying proportions, HNO₃, mixtures thereof, and strong bases such as NaOH or KOH.

The functionalized areas could be modified by means of chemical bonds or of a physical treatment.

At the surface of the substrate used in the present invention, at least two areas made up of different materials are provided. The substrate is therefore structured as various areas (various materials). This structuring can be carried out by microtechnology techniques (masking, photolithography, etching or deposition, demasking).

The areas may differ from one another, for example, in terms of hydrophilicity. In this case, the areas may derive from a single material, which can subsequently be chemically modified.

The chemical modification may also be, for example, the two-step conversion of an epoxide function to an aldehyde function in order to graft thereto molecules having amine-type groups. Similarly, an ester function may be converted to an acid function so as to produce surfaces which are hydrophilic and also reactive with respect to NH₂ functions.

The method of the present invention also comprises a successive functionalization with at least one chemical substance. The functionalization of a first area could also “pollute” a second area or successive areas by nonspecific adsorption of reactants used for this functionalization.

According to the present invention, it is therefore necessary to carry out:
(b1) a treatment of the second area and of the possible successive areas with a chemical substance Y¹ in order to clean from these areas the substance X¹ and/or its reaction products, which have been deposited on these areas during the functionalization of the first area, without damaging the functionalized surface of the first area.

It is not excluded that the cleaning (b1) and activating (b2) steps mentioned above be combined (same reactant used).

The method of the present invention could be used for the preparation of chemical or biological sensors, in the context of the fabrication of DNA chips, protein chips, sugar chips, peptide chips, small-organic-molecule chips for therapeutic purposes, and also for the preparation of microfluidic systems requiring functionalization of their walls.

In addition, the method of the present invention could be used for the preparation of any microelectronic device wherein it is necessary to confer mechanical or chemical properties on the surfaces of this device.

This invention makes it possible to differently functionalize two areas of a structured or nonstructured support (glass, polymers, silicon, mineral oxide layers, etc.) without protecting any one of the areas during the chemical process.

In fact, the present invention proposes an approach whose main advantage is that of being able to completely dissociate the technology steps (masking, etching, photolithography, etc.) and the chemical functionalization steps (cf. FIG. 3).

The following example also illustrates the present invention. This example is given by way of illustration and cannot be considered to be limiting.

### EXEMPLARY EMBODIMENT

The protocol described is an example of the method of the present invention. It integrates:
functionalizing the area A,
cleaning and activating the area B (simultaneously),
functionalizing the area B,
chemically modifying the functions of the area B.

A substrate consisting of two areas A and B is used, wherein the area A is made up of silicon and the area B of SiO₂ (500 nm) obtained by thermal oxidation of silicon.

The results obtained will be discussed in terms of contact angle. The contact angle is measured in the following way:

A drop of a liquid deposited on the planar surface of a solid body forms a contact angle at the interface between the liquid and the substrate. By definition, a drop is a liquid which does not wet and which has a contact angle of greater than 90°. Conversely, a drop of a liquid which wets has an angle of less than 90°.

Contact angle measurement is a method for characterizing the interaction between a liquid and a solid surface. The contact angle and the function of the surface tension of the liquid and of the surface free energy of the substrate are also called goniometry (C. J. Van Oz “Force interfaciale en milieu aqueux” [Interfacial force in aqueous medium], 1996).

When the two chemistries described hereinafter on separate substrates and without cleaning steps (not therefore necessary), the following contact angles are obtained:
103° on the area A
65-70° on the area B at the epoxide stage
55-60° on the area B at the diol stage.

### Functionalizing the Area A:

A surface of nonoxidized silicon is regenerated on the area A by immersing the substrate in dilute HF (1%) for a short period of time (a few tens of seconds) in order to limit consumption of the SiO₂ layer (area B). After optional rinsing with deionized water, the substrate is dried under a stream of nitrogen and then introduced into a reaction with 1-octadecene. The reaction is carried out under argon at 150° C. for 12 hours. The substrate is then rinsed successively with various solvents (heptane, dichloromethane, acetone, ethanol, water). The contact angle measurement indicates that the area A is functionalized (contact angle of 102° close to the theoretical 105° for a perfectly organized surface, table 1), whereas the area B is polluted with organic molecules (86°).

### Cleaning/Activating the Area B:

The following step (1% HF, 30 s) makes it possible to clean this area B and to activate it by creating silanol groups (contact angle of 13°) without notably degrading the area A (contact angle changing from 102° to 100°).

### Functionalizing the Area B:

The area B is then functionalized with a silane bearing an epoxide function according to one of the methods known in the art. The contact angle obtained (66°) is characteristic of this type of surface. It is obtained while almost entirely preserving the surface properties of the area A (change from 100° to 90°).

Chemical modification of the functions of the area B: the chemical conversion of the epoxide function to a diol function on the area B is carried out by means of an acid treatment (0.2N HCl for 3 hours at ambient temperature; contact angle=56°) without degrading the area A (contact angle of 90° conserved).

It was thus possible to localize two chemical functionalizations by formation of different covalent bonds on the same support without protecting any one of the areas during the chemical process.

TABLE 1
Surface contact angles

| | Area A | Area B |
|---|---|---|
| Steps | (Si) | (SiO₂) |
| After chemistry on area A | 102° | 86° |
| After cleaning | 100° | 13° |
| activating with HF | | |
| After chemistry on area B | 90° | 66° |
| epoxide stage | | |
| After chemistry on area B | 90° | 56° |
| diol stage | | |

The functionalization of the surface of the substrate is followed by spotting of the DNA strand probes.

### Spotting of DNA Strand Probes:

A solution of 20-mer oligomers (10 μM, phosphate buffer) modified with an NH₂ function reactive with respect to the aldehyde functions of the surface (5′ NH₂ TT TTT TCG GAT ACC CAA GGA 3′) is deposited onto this surface using a robot equipped with piezoelectric heads which eject drops of 330 pL.

After reaction for 12 hours at ambient temperature, a reducing post-treatment is carried out (0.1M NaBH₄) and the substrate is then rinsed with 0.2% SDS and with deionized water.

Hybridization with a complementary sequence:

The substrate is then immersed in a solution of complementary target (5′ GTC TCC TTG GGT ATC CGA TGT 3′) labeled with a CY3 flurophore. After incubation for 1 h at 50° C. in a Tris-EDTA buffer containing NaCl (pH=8.5), the chips are rinsed in various saline solutions, dried under argon and then read on a fluorescence scanner (excitation wavelength=532 nm). The image illustrated in FIG. 4 is obtained.

Thus, a DNA chip was prepared on a bifunctionalized substrate:
hydrophobic function outside these spots (area A, C₁₈ alkyl chain)
function reactive with respect to the biological molecules (area B, aldehyde).

Using an inorganic surface comprising two different materials (Si and SiO₂), a biochip was fabricated (chemical functionalization, spotting of biological probes) and used (hybridization with fluorescent targets) entirely without masking any one of the areas of the surface.

This technology therefore makes it possible to obtain spots of excellent quality, in particular in terms of size and alignment (conditioned by the design of the underlying inorganic materials), but also in terms of homogeneity within a spot.

Another example, which functions in principle like exemplary embodiment number 1, makes use of a substrate whose surface comprises a multitude of areas. The multitude of the different areas is divided by groups of the areas consisting of the same material. In extremis, each area of the multitude (several tens, or even several hundred) of the areas may consist of a different material.

The material of the multitude of areas was gold and silicon oxide, i.e. the substrate comprised two groups of areas, wherein each group is made up of a different material.

The chemical substance, the reactant X¹, is preferably a thiol, and the reactant X² is a silane or a siloxane. Hydrofluoric acid (HF) is preferred as reactant Y¹, Y² and Y.

Another substrate consisted of three groups of areas comprising different materials; in particular, one group consists of a multitude of areas of gold, the second group consists of a silicon oxide and the third group consists of pure silicon. The reactant X¹ is chosen from alkenes, alkynes and halogens. The reactant Y is HF or H₂SO₄, the reactant X² is a thiol, the reactant Y is hydrofluoric acid HF and the reactant X³ is a silane or a siloxane.

1. A method for successively functionalizing a substrate, whose surface is provided with at least two areas (1, 2) made up of different materials, with at least one chemical substance, comprising the steps of:
(a) functionalizing a first area (1) without masking the second area (2) or the possible successive areas by transforming the substrate with a chemical substance X¹, and forming a covalent bond between the chemical substance X¹ and the first-area material (1), wherein the reactivity of the first-area material is greater with respect to the substance X¹ than the reactivity of the materials of the possible successive areas with respect thereto, and forming a covalent bond between the chemical substance X¹ and the first-area material (1), and
(b1) treating the second area (2) and/or the possible successive areas with a chemical substance Y¹ in order to clean from these areas the substance X¹ and/or its reaction products, which have been deposited on these areas during the functionalization of the first area (1), without damaging the functionalized surface of the first area (1).

2. The method as claimed in claim 1, characterized in that the following step is also carried out:
(c) functionalizing a second area (2) without masking the successive areas by transforming the substrate with a chemical substance X² different than X¹, wherein the reactivity of the second-area material is greater with respect to the substance X² than the reactivity of the other materials, and forming a bond between the chemical substance X² and the second-area material (2); and eliminating from the third area or from the possible successive areas, when these areas are present.

3. The method as claimed in claim 1, characterized in that, before the functionalization, the following step is carried out:
(b2) chemically or physically activating the second area (2) and the possible successive areas with a view to functionalization, by treating with a chemical substance Y different than the chemical substances X¹ and X².

4. The method as claimed in claim 1, characterized in that steps (b1), (b2) and/or (c) are repeated one or more times, it being possible to use, in steps (a) and (c), chemical substances X different than X¹ and X² and, in steps (b1) and/or (b2), chemical substances Y different than Y¹ and than Y².

5. The method as claimed in claim 1, characterized in that Y¹ is identical to Y².

6. The method as claimed in claim 1, characterized in that step (b1) and/or step (b2) is carried out in an acidic or basic medium.

7. The method as claimed in claim 1, characterized in that there is at least one area (1) made up of conducting or semiconducting materials that can react thermally, photochemically or mechanochemically with chemical substances X¹, X² or X, the molecules of which possess a chemical functionality reactive with respect to these materials, in order to form a chemical bond, in particular a covalent bond.

8. The method as claimed in claim 7, characterized in that the conducting or semiconducting materials are selected from those of the group comprising silicon, crystalline or amorphous carbon and metals.

9. The method as claimed in claim 1, characterized in that there is at least one area (2) made up of a material selected from those of the group comprising metal or semimetallic nitrides or oxides, or a mixture of these materials, and polymers.

10. The method as claimed in claim 1, characterized in that the chemical substances Y¹, Y² or Y are chosen from those of the group comprising HF, H₂SO₄, H₂O₂, HNO₃, and mixtures thereof, or strong bases.

11. The method as claimed in claim 1, characterized in that the functionalized areas are modified by means of chemical bonds or of a physical treatment.

12. A microstructure containing areas which consist of various materials, wherein at least one area is functionalized by covalent bonding, that can be carried out by a method as claimed in claim 1.
